(19) United States
(12) Patent Application Publication
(10) Pub. No.: US 2026/0000935 A1
(43) Pub. Date: Jan. 1, 2026

(54) MOTION DETECTION DEVICE AND METHOD USING EARTH'S MAGNETIC FIELD

(71) Applicant: POSTECH RESEARCH AND BUSINESS DEVELOPMENT FOUNDATION, Pohang-si (KR)

(72) Inventors: Inseok Hwang, Pohang-si (KR); Young-Joo Suh, Pohang-si (KR); Jiha Kim, Pohang-si (KR); Younho Nam, Pohang-si (KR); Jungeun Lee, Pohang-si (KR)

(73) Assignee: POSTECH RESEARCH AND BUSINESS DEVELOPMENT FOUNDATION, Pohang-si (KR)

(21) Appl. No.: 18/973,156

(22) Filed: Dec. 9, 2024

(30) Foreign Application Priority Data
Jul. 1, 2024 (KR) 10-2024-0086028

(51) Int. Cl. A63B 24/00; G01R 33/00; G01R 33/02

(52) U.S. Cl. CPC A63B 24/0062; G01R 33/0047; G01R 33/02

(57) ABSTRACT

Disclosed is a motion detection device and method using Earth's magnetic field. The motion detection device using the Earth's magnetic field comprises a geomagnetic field sensor, a processor, and a memory operatively connected to the processor, wherein the memory stores instructions and when executed, enable the processor: to identify a first geomagnetic field data using the geomagnetic field sensor, based on the motion detection device that is not moving; to identify that the first geomagnetic field data is generated from a first exercise equipment that is moving; and to identify at least one of a type of exercise and a number of times (e.g., reps, sets) of the exercise using the first exercise equipment based on the first geomagnetic field data

### TECHNICAL FIELD

The present invention relates to a motion detection device and method using Earth's magnetic field.

### BACKGROUND ART

The content of this section merely provides background information as to the present embodiments (of the present invention) and is not construed as prior art.

In general, motion detection devices are implemented in apparatuses worn on the body of a user) to detect body movements, or additional sensors are attached to exercise equipment to directly detect movement of the exercise equipment to recognize movement(s). In such cases, movement is mainly recognized using an accelerometer and a gyrometer.

On the other hand, when movement is recognized using an accelerometer and a gyrometer, there may be a limitation that movement cannot be recognized if the body part on which the device with the motion detection apparatus implemented therein does not move. Also, even if additional sensors are attached to exercise equipment to make attachment of the device on a body part unnecessary, the increased cost for the additional sensors cannot be avoided.

Therefore, there has been a need for technology that can recognize the user's movement even when the device with the motion detection apparatus implemented therein is not worn.

### SUMMARY OF INVENTION

### Technical Problem

An object of the present invention is to provide a motion detection device and method using Earth's magnetic or geomagnetic field that recognizes the user's movement using the geomagnetic field even when the body part on which the device is worn does not move.

Also, an object of the present invention is to provide a motion detection device and method using the geomagnetic field that may recognize the user's movement using the geomagnetic field even when the device and the user are separated and apart from one another.

The objects of the present invention are not limited to the objects above, and other objects and advantages of the present invention that are not mentioned may be understood by the following description, and will be more clearly understood by embodiments of the present invention. Also, it will be easily understood that the objects and advantages of the present invention may be realized by the means and combinations thereof indicated in the patent claims.

### Technical Solutions

According to an embodiment of the present invention, a motion detection device using Earth's magnetic field comprises a geomagnetic field sensor, a processor, and a memory operatively connected to the processor, wherein the memory enables the processor when executed to: identify a 1st geomagnetic field data using the geomagnetic field sensor, based on that the motion detection device is not moving; identify that the 1st geomagnetic field data is generated from a 1st exercise equipment that is moving; and store instructions to identify at least one of a type of exercise and a number of the exercise using the 1st exercise equipment, based on the 1st geomagnetic field data.

Also, the instructions enables the processor to: identify a plurality of geomagnetic field data using the geomagnetic field sensor; and identify the 1st exercise equipment from which the 1st geomagnetic field data is generated, based on the 1st geomagnetic field data having a strongest intensity among the plurality of the geomagnetic field data.

Also, a plurality of exercise equipment comprises a 1st exercise equipment and a 2nd exercise equipment, and the instructions enables the processor to: identify the 1st geomagnetic field data and the 2nd geomagnetic field data, using the geomagnetic field sensor; and identify the 1st exercise equipment from which the 1st geomagnetic field data is generated, based on the 1st geomagnetic field data having a stronger intensity among the 1st geomagnetic field data and the 2nd geomagnetic field data.

Also, the instructions enables the processor to: identify the 1st geomagnetic field data and the 2nd geomagnetic field data, using the geomagnetic field sensor; identify that the 2nd geomagnetic field data is generated from a 2nd exercise equipment that is moving; identify an input for selecting the 1st exercise equipment among the 1st exercise equipment and the 2nd exercise equipment; and based on the input, identify at least one of the type and the number of the exercise using the 1st exercise equipment, based on the 1st geomagnetic field data.

Also, the instructions enables the processor to: based on the input, perform pre-processing on the 1st geomagnetic field data and identify the 1st geomagnetic field data that is pre-processed; and identify at least one of the type and number of the exercise using the 1st exercise equipment, based on the pre-processed 1st geomagnetic field data.

Also, the instructions enables the processor to: identify a position of the motion detection device that is not moving; identify a direction of gravity; and pre-process the 1st geomagnetic field data based on a difference of the position of the motion detection device and the direction of gravity, and identify the pre-processed 1st geomagnetic field data.

Also, the instructions enables the processor to: pre-process the 1st geomagnetic field data, and identify the pre-processed 1st geomagnetic field data; and identify at least one of the type and the number of the exercise using the 1st exercise equipment, based on the pre-processed 1st geomagnetic field data.

Also, the instructions enables the processor to: identify a position of the motion detection device that is not moving; identify the direction of gravity; and pre-process the 1st geomagnetic field data based on a difference of the position of the motion detection device and the direction of gravity, and identify the pre-processed 1st geomagnetic field data.

Also, the instructions enables the processor to: identify whether the motion detection device is moving by using at least one of an accelerometer and a gyrometer, which are included in the motion detection device; and identify the 1st geomagnetic field data using the geomagnetic field sensor, based on that the motion detection device is not moving.

Also, the motion detection device comprising the geomagnetic field sensor is a mobile device.

According to an embodiment of the present invention, a motion detection method using Earth's magnetic field, comprises: a step of identifying a 1st geomagnetic field data using a geomagnetic field sensor, based on that the motion detection device comprising the geomagnetic field sensor is not moving; a step of identifying that the 1st geomagnetic field data is generated from a 1st exercise equipment that is moving; and a step of identifying at least one of a type of exercise and a number of the exercise using the 1st exercise equipment, based on the 1st geomagnetic field data.

The motion detection method using Earth's magnetic field further comprises a step of identifying a plurality of geomagnetic field data using the geomagnetic field sensor; and wherein the step of identifying the 1st geomagnetic field data using the geomagnetic field sensor comprises a step of identifying the 1st geomagnetic field data having a strongest intensity among the plurality of the geomagnetic field data.

Also, a plurality of exercise equipment comprises a 1st exercise equipment and a 2nd exercise equipment; and the step of identifying the 1st geomagnetic field data having the strongest intensity among the plurality of the geomagnetic field data, comprises: a step of identify the 1st geomagnetic field data and the 2nd geomagnetic field data, using the geomagnetic field sensor, and a step of identifying an intensity of the 1st geomagnetic field data and an intensity of the 2nd geomagnetic field data.

The motion detection method using Earth's magnetic field further comprises: a step of identifying the 1st geomagnetic field data and a 2nd geomagnetic field data, using the geomagnetic field sensor; a step of identifying that the 2nd geomagnetic field data is generated from the 2nd exercise equipment that is moving; and a step of identify an input for selecting the 1st exercise equipment among the 1st exercise equipment and the 2nd exercise equipment; and wherein based on the input, the step of identifying at least one of the type and the number of the exercise using the 1st exercise equipment, based on the 1st geomagnetic field data, comprises a step of selecting the 1st geomagnetic field data, based on the input.

The motion detection method using Earth's magnetic field further comprises a step of pre-processing the 1st geomagnetic field data and identifying the pre-processed 1st geomagnetic field data, and wherein the step of identifying at least one of the type and the number of the exercise using the 1st exercise equipment is performed based on the pre-processed 1st geomagnetic field data.

Also, the step of pre-processing the 1st geomagnetic field data and identifying the pre-processed 1st geomagnetic field data, comprises: a step of identifying a position of the motion detection device that is not moving; a step of identifying a direction of gravity; and a step of pre-processing the 1st geomagnetic field data based on a difference of the position of the motion detection device and the direction of gravity, and identifying the pre-processed 1st geomagnetic field data.

The motion detection method using Earth's magnetic field further comprises a step of pre-processing the 1st geomagnetic field data, and identifying the pre-processed 1st geomagnetic field data; and wherein the step of identifying at least one of the type and the number of the exercise using the 1st exercise equipment is performed based on the pre-processed 1st geomagnetic field data.

Also, the step of pre-processing the 1st geomagnetic field data, and identifying the pre-processed 1st geomagnetic field data, comprises: a step of identifying a position of the motion detection device that is not moving; a step of identifying the direction of gravity; and a step of pre-processing the 1st geomagnetic field data based on a difference of the position of the motion detection device and the direction of gravity, and identifying the pre-processed 1st geomagnetic field data.

The motion detection method using Earth's magnetic field further comprises: a step of identifying whether the motion detection device is moving by using at least one of an accelerometer and a gyrometer, which are included in the motion detection device; and a step of identifying the 1st geomagnetic field data using the geomagnetic field sensor, based on that the motion detection device is not moving.

Also, the motion detection device comprising the geomagnetic field sensor is a mobile device.

### Advantageous Effects

The motion detection device using Earth's magnetic field according to the present invention recognizes the user's movement using a geomagnetic field even if the body part of the user on which the device is worn does not move; thus, when the geomagnetic field sensor is already included in a device that is commercialized, the movement of an exercise equipment near the device may be identified, and the movement may be detected without additional cost.

In addition, the motion detection device using Earth's magnetic field according to the present invention recognizes the user's movement using a geomagnetic field even if the device and the user are separated and apart from one another; thus, even if the user fixes the device at a certain location or position during an exercise and performs an exercise, the movement of an exercise equipment near the device may be identified, and user convenience may be increased.

In addition, the motion detection method using Earth's magnetic field according to the present invention recognizes the user's movement using a geomagnetic field even if the body part of the user on which the device is worn does not move; thus, when the geomagnetic field sensor is already included in a device that is commercialized, the movement of an exercise equipment near the device may be identified, and the movement may be detected without additional cost.

In addition, the motion detection method using Earth's magnetic field according to the present invention recognizes the user's movement using a geomagnetic field even if the device and the user are separated and apart from one another; thus, even if the user fixes the device at a certain location or position during an exercise and performs an exercise, the movement of an exercise equipment near the device may be identified, and user convenience may be increased.

In addition to the advantages described above, specific advantages of the present invention will be described further while explaining details for carrying out the invention below.

### BRIEF DESCRIPTION OF THE DRAWINGS

FIG. 1 shows a diagram for describing a motion detection device using Earth's magnetic field, according to an embodiment of the present invention.

FIG. 2 shows a diagram for describing an operation of a processor of a motion detection device using Earth's magnetic field.

FIG. 3 and FIG. 4 show diagrams for describing steps S100, S200, and S300 of FIG. 2.

FIG. 5 shows a diagram for describing an operation of a processor of a motion detection device using Earth's magnetic field, according to an embodiment of the present invention.

FIG. 6 shows a diagram for describing step S400 of FIG. 5.

FIG. 7 shows a diagram for describing an operation of a processor of a motion detection device using Earth's magnetic field, according to an embodiment of the present invention.

FIG. 8 shows a diagram for describing step S101 of FIG. 7.

an operation of a processor of a motion detection device using Earth's magnetic field.

FIG. 9 and FIG. 10 show diagrams for describing an operation of a processor of a motion detection device using Earth's magnetic field, according to embodiments of the present invention.

FIG. 11 shows a diagram for describing an operation of a processor of a motion detection device using Earth's magnetic field, according to an embodiment of the present invention.

FIG. 12 shows a flowchart for describing a motion detection method using Earth's magnetic field, according to an embodiment of the present invention.

### DETAILED DESCRIPTION OF INVENTION

Terms or words used in the present specification and claims should not be limited to and interpreted as having ordinary meanings or dictionary definitions. In accordance with the principle that the inventor can define the terms or words in order to explain his or her invention in the best way, they should be interpreted with a meaning and concept consistent with the technical spirit and scope of the present invention. Additionally, embodiments described in this specification and the configurations shown in the drawings are merely embodiments of the present invention and do not represent the technical spirit and scope of the present invention in its entirety. Thus, it should be understood that there may be various equivalents, modifications, and other examples that may be applied, that can replace the embodiments at the time of filing the present application.

Terms such as “first (1^{st}),” “second (2^{nd}),” A, B, etc. used in the present specification and claims may be used to describe various elements and/or parts but the elements and/or parts should not be limited by these terms. These terms are used only to distinguish one element and/or part from another. For instance, a first element may be termed a second element and vice versa, without departing from the scope of the present invention. Term(s) “and/or” may include any one or a plurality of related elements or items described.

Terms used in the present specification and claims are used for the purpose of describing particular exemplary embodiments only and are not intended to limit the present invention. Singular terms or forms include the plural forms as well, unless the context clearly indicates otherwise. The terms or language “comprising,” “including,” “having,” etc. are intended to indicate the presence of described features, numbers, steps, operations, components, elements, and/or combination thereof, as described in the present specification, and should not be understood as precluding the presence or addition of one or more of other features, numbers, steps, operations, components, elements, and/or combination thereof.

Unless otherwise defined, all terms (including technical and scientific terms) used herein have same meaning as those commonly understood by a person with ordinary skill in the art to which this invention pertains.

Terms, such as those defined in commonly used dictionaries, should be interpreted as having meaning that is consistent with their meaning in the context of the relevant art and should not be interpreted in an idealized or overly formal sense, unless expressly, so defined herein. Additionally, each configuration, process, manufacturing process, or method, etc. included in each embodiment of the present invention may be shared when not contradictory to each other in technical sense.

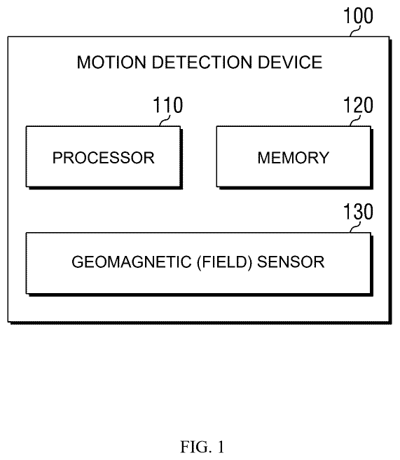

FIG. 1 shows a diagram for describing a motion detection device using Earth's magnetic field, according to an embodiment of the present invention.

Referencing FIG. 1, the motion detection device using Earth's magnetic field (100) (hereinafter, also referred to as the motion detection device (100)) may comprise a processor (110), memory (120) and a geomagnetic sensor or geomagnetic field sensor (130).

One or more of other components or elements (e.g., a communication module) may be added to the motion detection device (100). In another embodiment, a number of these components may be implemented as a single integrated circuit.

The motion detection device (100) may be a portable device. The motion detection device (100) may, for example, be a mobile device, which is a small computer device such as a smart phone that may be carried inside a pocket.

According to an embodiment of the present invention, the motion detection device (100) may reduce the cost of purchasing additional devices by detecting movement around the device using the geomagnetic field sensor (130) included in a portable device (e.g., a mobile device) that is already commercialized.

The memory (120) may store various data used by at least one component (e.g., the processor (110)) of the motion detection device (100). The data may include, for example, input data or output data for software (e.g., a program) and commands related thereto. The memory (120) may include volatile memory or nonvolatile memory.

The memory (120) may store commands, information, or data related to the operations of the components included in the motion detection device (100). For example, the memory (120) may store instructions that, when executed, enable the processor (110) to perform various operations described in the present disclosure.

The processor (110) may be operatively coupled to the memory (120) to perform an overall function of the motion detection device (100). The processor (110) may include, for example, one or more processors. The one or more processors may include, for example, an image signal processor (ISP), an application processor (AP), or a communication processor (CP).

The processor (110) may control at least one other component (e.g., hardware or software component) of the motion detection device (100), which is/are connected to the processor (110) by executing, for example, software (e.g., a program), and may perform various data processing or calculations. According to an embodiment, as at least a part of the data processing or calculations, the processor (110) may load a command or data received from another/other component (e.g., a communication module) into the memory (120), process the command or data stored in the memory (120), and store result data in the memory (120). According to an embodiment, the processor (110) may include a main processor (e.g., a central processing unit or an application processor), and an auxiliary processor (e.g., a graphics processing unit, an image signal processor, a sensor hub processor, or a communication processor) that may operate independently or together therewith. As an addition or alternatively, the auxiliary processor may be configured to use lower power than the main processor, or to be specialized for a given function. The auxiliary processor may be implemented separately from the main processor, or as part thereof. The program may be stored as software in memory (120) and may include, for example, an operating system, middleware, or applications.

The processor (110) may identify a 1st geomagnetic field data using the geomagnetic field sensor (130) based on that the motion detection device (100), which includes the geomagnetic field sensor (130), is not moving. The processor (110) may identify that the 1st geomagnetic field data is generated from a 1st exercise equipment that moves or is moving. The processor (110) may identify at least one of a type of the 1st exercise equipment, a type of exercise using the 1st exercise equipment, and a number of the exercise based on the 1st geomagnetic field data.

The geomagnetic field sensor (130) is a sensor for finding a cardinal point or direction, and may measure the movement, direction, and number of exercise of the exercise equipment by measuring Earth's magnetic field. When the motion detection device using the Earth's magnetic field (100) is a portable device (e.g., a mobile device), the geomagnetic field sensor (130) may have been included in advance in the motion detection device (100).

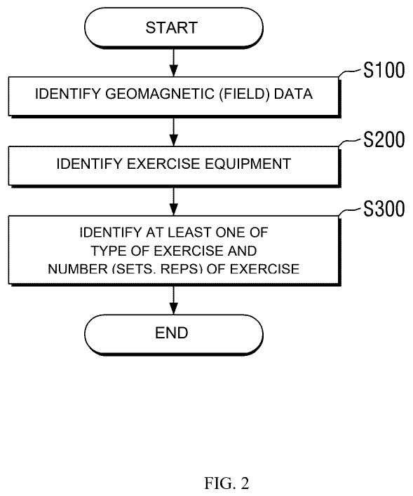

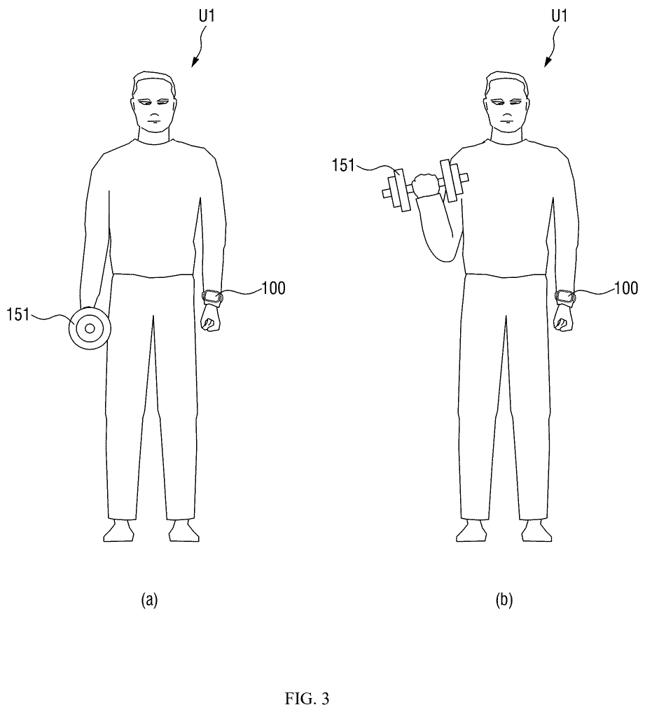

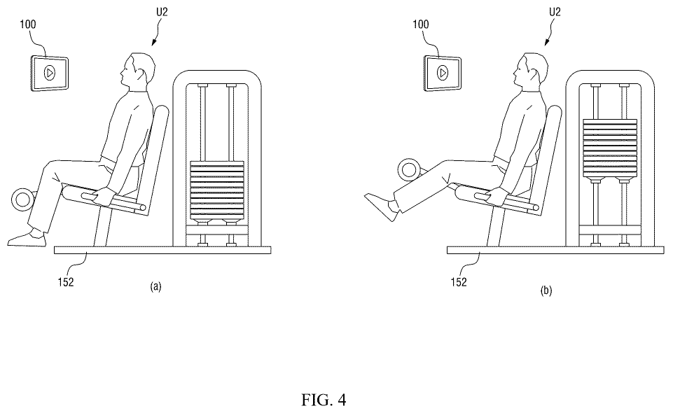

FIG. 2 shows a diagram for describing an operation of the processor of the motion detection device using Earth's magnetic field. FIG. 3 and FIG. 4 show diagrams for describing steps S100, S200, and S300 of FIG. 2.

Referencing FIG. 1, FIG. 2, FIG. 3, and FIG. 4, the processor (110) of the motion detection device (100), according to an embodiment of the present invention, may first identify a geomagnetic data or geomagnetic field data (S100). The processor (110) may identify geomagnetic field data detected through the geomagnetic field sensor (130). The geomagnetic field data may be generated from a moving exercise equipment. The geomagnetic field data may be periodic data. As the exercise equipment, which is of a ferromagnetic material (e.g., steel), moves, interference in a surrounding magnetic field occurs, and the geomagnetic field data may be sensed through the geomagnetic field sensor (130). The processor (110) may identify the geomagnetic field data detected or sensed by the geomagnetic field sensor (130).

The processor (110) may identify a/the geomagnetic field data based on that the motion detection device (100) is not moving.

According to an embodiment of the present invention, the motion detection device (100) may detect a movement of a user even when the user exercises another body part while keeping still the body part on which the motion detection device (100) is attached. For example, as shown in FIG. 3, a 1st user (U1) may perform an exercise using the body part on which the motion detection device (100) is not worn and a 1st exercise equipment (151). The 1st exercise equipment (151) may be of a ferromagnetic material (e.g., steel). When the body part on which the 1st user (U1) wears the motion detection device (100) is kept still and the 1st user exercises the body part on which the motion detection device (100) is not worn, the motion detection device (100) may be identified as not moving. Even if the motion detection device (100) is firmly mounted or fixed, magnetic field interference occurs due to the movement of the 1st motion device (151), so that the geomagnetic field data may be identified through the geomagnetic field sensor (130).

According to an embodiment of the present invention, the motion detection device (100) may detect the user's movement even when the user performs an exercise while fixing the motion detection device (100) to a certain location. For example, as shown in FIG. 4, a 2nd user (U2) may perform an exercise using a 2nd exercise equipment (152) while fixing the motion detection device (100) to a certain location or position, which is disposed apart from the 2nd user (U2). The 2nd exercise equipment (152) may be of a ferromagnetic material (e.g., steel). When the 2nd user (U2) performs an exercise while fixing the motion detection device (100) to a certain location or position, and apart from the 2nd user (U2), magnetic field interference occurs due to the movement of the 2nd exercise equipment (152), so that geomagnetic field data may be identified through the geomagnetic field sensor (130).

The processor (110) may identify a/the exercise equipment (S200). The processor (110) may identify the exercise equipment from which the geomagnetic field data is generated based on the geomagnetic field data sensed by the geomagnetic field sensor (130). The exercise equipment may be of a ferromagnetic material (e.g., steel). For example, the processor (110) may identify that the geomagnetic field data is generated from a specific exercise equipment that is moving.

The processor (110) may identify the types of exercise and the exercise equipment based on a periodicity of the geomagnetic field data. The processor (110) may identify a main component vector based on the periodicity of the geomagnetic field data. The processor (110) may identify the types of exercise and the exercise equipment based on features that may be extracted from the main component vector, including a direction and magnitude of the main component vector.

In certain embodiments, the processor (110) may determine the type of exercise currently being performed and identify the exercise equipment, via a model using machine learning.

Referencing FIG. 3, the processor (110) may identify the moving 1st exercise equipment (151) based on the identified geomagnetic field data. The processor (110) may identify that the identified geomagnetic field data is generated from the 1st exercise equipment (151). When the 1st user (U1) performs an exercise by moving the 1st exercise equipment (151), the geomagnetic field data is sensed by the geomagnetic field sensor (130), so the processor (110) may identify that the exercise equipment that the 1st user (U1) is moving is the 1st exercise equipment (151).

Referencing FIG. 4, the processor (110) may identify the moving 2nd exercise equipment (152) based on the identified geomagnetic field data. The processor (110) may identify that the identified geomagnetic field data is generated from the 2nd exercise equipment (152). When the 2nd user (U2) performs an exercise by moving the 2nd exercise equipment (152), since the geomagnetic field data is sensed by the geomagnetic field sensor (130), the processor (110) may identify that the exercise equipment that the 2nd user (U2) is moving is the 2nd exercise equipment (152).

The processor (110) may identify at least one of the type of exercise and the number of the exercise (e.g., how many times an exercise is performed) based on the geomagnetic field data (S300). The processor (110) may identify a/the main component vector based on the periodicity of the geomagnetic field data. The processor (110) may identify the type of the exercise equipment based on a feature that may be extracted from the main component vector, including the direction and magnitude of the main component vector, and identify at least one of the type of exercise and the number of the exercise.

In certain embodiments, the processor (110) may estimate the type of exercise currently being performed and the number of exercise, via a model using machine learning.

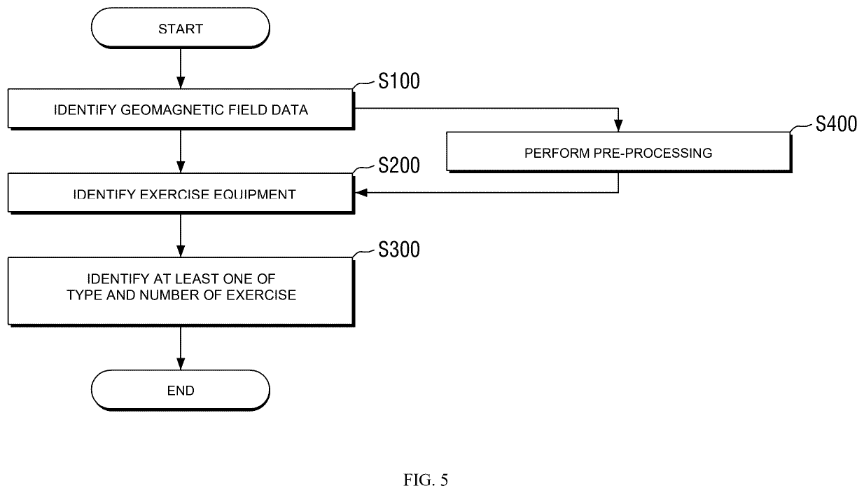

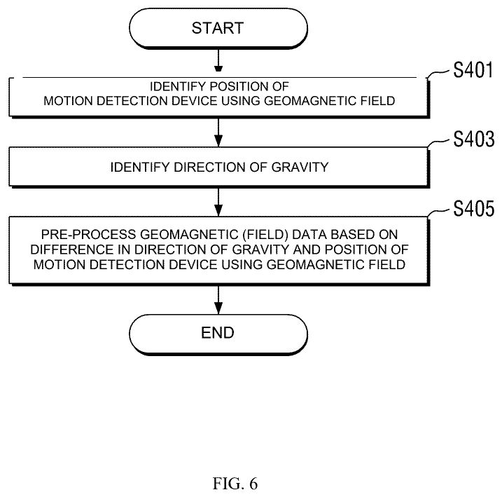

FIG. 5 shows a diagram for describing an operation of the processor of the motion detection device using Earth's magnetic field, according to an embodiment of the present invention. FIG. 6 shows a diagram for describing step S400 of FIG. 5. For clarity of explanation, any details that overlap with those explained previously are simplified or omitted.

Referencing FIG. 1, FIG. 5, and FIG. 6, the processor (110) of the motion detection device (100), according to an embodiment of the present invention, may identify geomagnetic field data (S100) and then perform pre-processing (S400). The processor (110) may perform pre-processing on the identified geomagnetic field data. Based on the pre-processed geomagnetic field data, the processor (110) may identify the exercise equipment (S200) and identify at least one of the type of exercise and the number of the exercise (S300).

In order to pre-process the identified geomagnetic field data, the processor (110) may first identify a location or position of the motion detection device (100) (S401). In addition, the processor (110) may identify a direction of gravity (S403). Steps S401 and S403 may be performed in reverse order or may be performed simultaneously.

The processor (110) may pre-process the geomagnetic field data based on a difference between the direction of gravity and the position of the motion detection device (100) (S405). The processor (110) may pre-process the geomagnetic field data by compensating for the difference between the direction of gravity and the position of the motion detection device (100) so that the geomagnetic field data becomes identical to data obtained from a/the device aligned with the direction of gravity.

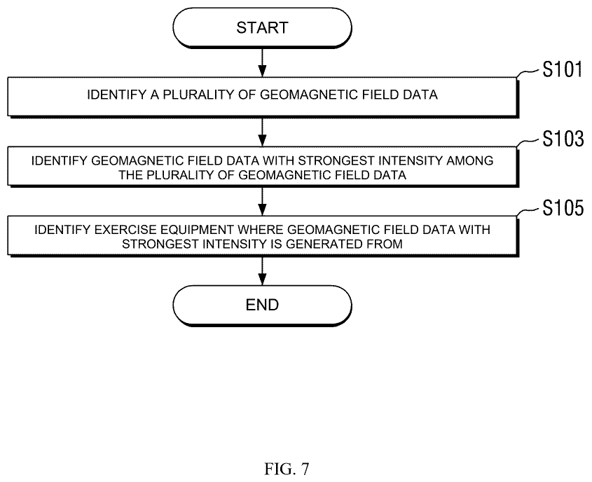

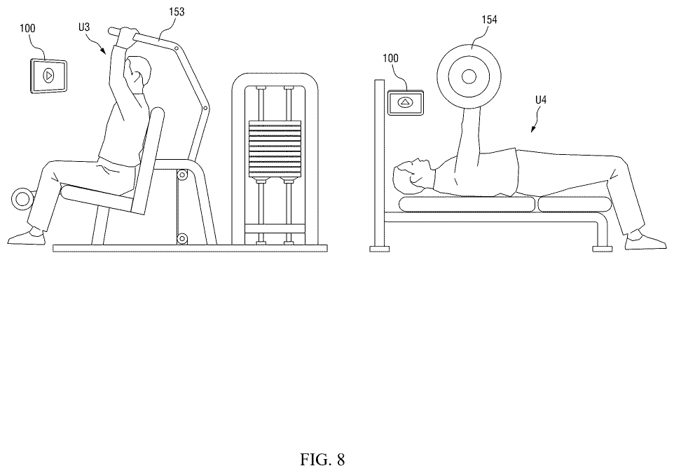

FIG. 7 shows a diagram for describing an operation of a processor of a motion detection device using Earth's magnetic field, according to an embodiment of the present invention. FIG. 7 shows a diagram for describing step S100 of FIG. 2. FIG. 8 shows a diagram for describing step S101 of FIG. 7. For clarity of explanation, any details that overlap with those explained previously are simplified or omitted.

Referring to FIG. 1, FIG. 2, FIG. 7, and FIG. 8, the processor (110) of the motion detection device (100), according to an embodiment of the present invention, may identify the 1st geomagnetic field data among a plurality of geomagnetic field data (S100).

The processor (110) may first identify a plurality of geomagnetic field data (S101). For example, as shown in FIG. 8, when a plurality of exercise equipment (153, 154) exists and each of the plurality of the exercise equipment (153, 154) is moving, the processor (110) may identify the 1st geomagnetic field data and the 2nd geomagnetic field data through the geomagnetic field sensor (130).

The processor (110) may identify the geomagnetic field data having a strongest intensity among the plurality of geomagnetic field data (S103). The processor (110) may identify, for example, the 1st geomagnetic field data having the strongest intensity among a plurality of geomagnetic field data.

The processor (110) may identify the exercise equipment from which the strongest geomagnetic field data is generated (S105). For example, the processor (110) may identify that the exercise equipment from which the 1st geomagnetic field data is generated is the 3rd exercise equipment (153) among the plurality of exercise equipment (153, 154). The processor (110) may identify the type of the exercise equipment based on the periodicity of the 1st geomagnetic field data and identify that the exercise equipment from which the 1st geomagnetic field data is generated is the 3rd exercise equipment (153).

For example, when the user of the motion detection device (100) is a 3rd user (U3), a 4th exercise equipment (154) being moved by a 4th user (U4) may exist in a vicinity of the 3rd user (U3). The 3rd user (U3) may be performing an exercise using the 3rd exercise equipment (153). The 3rd exercise equipment (153) and the 4th exercise equipment (154) may be of a ferromagnetic material (e.g., steel). The processor (110) may identify the 1st geomagnetic field data and the 2nd field geomagnetic field data using the geomagnetic field sensor (130). The processor (110) may identify whichever is stronger of the intensity of the 1st geomagnetic field data and the intensity of the 2nd geomagnetic field data. The processor (110) may identify the 3rd exercise equipment (153) from which the 1st geomagnetic field data is generated, based on the intensity of the 1st geomagnetic field data being stronger. The processor (110) may identify the type of the 3rd exercise equipment (153) based on the periodicity of the 1st geomagnetic field data, and may identify at least one of the type of exercise and the number of the exercise.

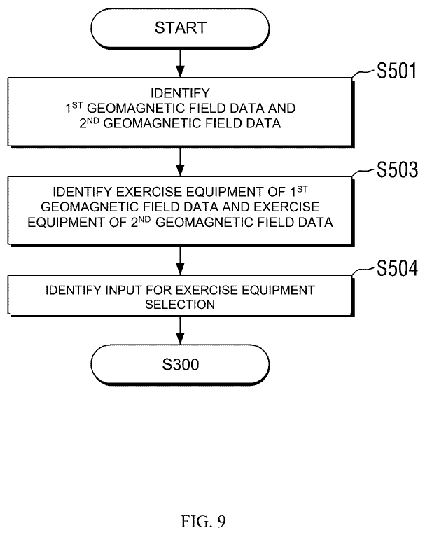

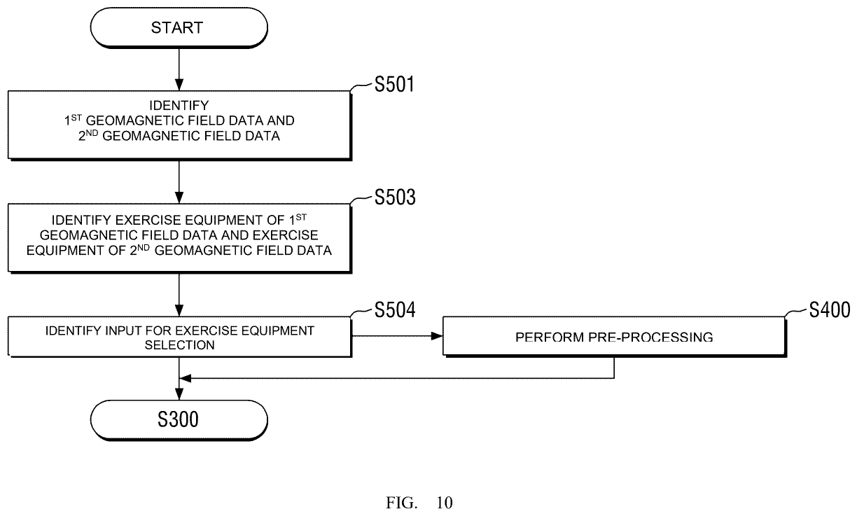

FIG. 9 and FIG. 10 show diagrams for describing an operation of the processor of the motion detection device using Earth's magnetic field, according to embodiments of the present invention. For clarity of explanation, any details that overlap with those explained previously are simplified or omitted.

Referencing FIG. 1, FIG. 2 and FIG. 9, the processor (110) of the motion detection device (100), according to an embodiment of the present invention, may perform step S300 after performing steps S501, S503 and S504 instead of steps S100 and S200 of FIG. 2.

The processor (110) may identify the 1st geomagnetic field data and the 2nd geomagnetic field data using the geomagnetic field sensor (130) (S501).

The processor (110) may identify each of the 1st exercise equipment from which the 1st geomagnetic field data is generated and the 2nd exercise equipment from which the 2nd geomagnetic field data is generated (S503). The processor (110) may identify the 1st exercise equipment by determining the type of exercise based on the periodicity of the 1st geomagnetic field data. In addition, the processor (110) may identify the 2nd exercise equipment by determining the type of exercise based on the periodicity of the 2nd geomagnetic field data.

The processor (110) may identify an input for selection of the exercise equipment (S504). For example, the processor (110) may provide the user with information for the 1st exercise equipment identified based on the 1st geomagnetic field data and the 2nd exercise equipment identified based on the 2nd geomagnetic field data, and receive the exercise equipment selection input from the user to select the exercise equipment currently being exercised with/on between the 1st exercise equipment and the 2nd exercise equipment.

The processor (110) may identify at least one of the type of exercise and the number of the exercise using the selected exercise equipment based on the exercise equipment selection input (S300).

Referencing FIG. 10, in certain embodiments, the processor (110) may further perform pre-processing (S400). The processor (110) may perform pre-processing on the geomagnetic field data for the selected exercise equipment based on the identified exercise equipment selection input. The processor (110) may identify at least one of the type of exercise and the number of the exercise using the selected exercise equipment based on the pre-processed geomagnetic field data.

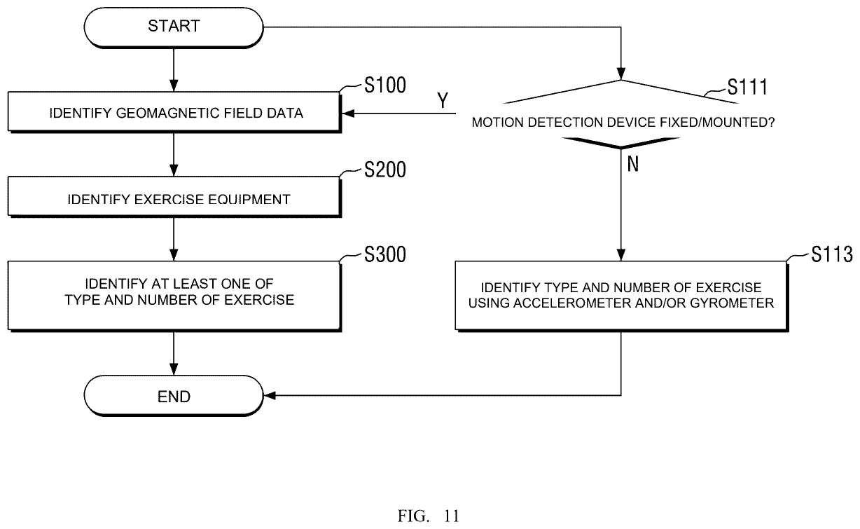

FIG. 11 shows a diagram for describing an operation of the processor of the motion detection device using Earth's magnetic field, according to an embodiment of the present invention. For clarity of explanation, any details that overlap with those explained previously are simplified or omitted.

Referencing FIG. 1 and FIG. 11, the processor (110) of the motion detection device (100), according to an embodiment of the present invention, may determine whether the motion detection device (100) is fixed (S111). The processor (110) may identify whether the motion detection device (100) is moving by using at least one of the accelerometer and the gyrometer, which are included in the motion detection device (100).

The processor (110) may identify the type and number of exercise by using the accelerometer and/or the angular velocity, which are included in the motion detection device (100), based on that the motion detection device (100) is not fixed and is moving (N in S111) (S113). The processor (110) may identify whether the motion detection device (100) is moving by using the accelerometer and/or the angular velocity, which are included in the motion detection device (100).

For example, if the user performs an exercise on or with respect to a body part on which the motion detection device (100) is worn and the body part is moving, the processor (110) may identify the type and number of exercise by using the accelerometer and/or the gyrometer.

In certain embodiments, the processor (110) may identify the type and number of exercise using at least one of the accelerometer, a gyrometer, and a magnetometer, which are included in the motion detection device (100), based on that the motion detection device (100) is not fixed and is moving (N in S111). For example, if the user is performing an exercise on a body part on which the motion detection device (100) is worn and the body part is moving, the processor (110) may identify the type and number of exercise using not only the accelerometer and/or the gyrometer but also the magnetometer.

The processor (110) may identify the geomagnetic field data using the geomagnetic field sensor (130) based on that the motion detection device (100) is fixed and is not moving (Y in S111), identify the type of exercise equipment based on the geomagnetic field data (S100), identify the exercise equipment based on the geomagnetic field data (S200), and identify the type and number of exercise based on the geomagnetic field data.

According to an embodiment of the present invention, the motion detection device (100) uses a geomagnetic field sensor included in a device already in use (e.g., a portable device, a mobile device) to identify the geomagnetic field data generated from an exercise equipment being used by the user, identifies the type of exercise based on the geomagnetic field data, and identifies the exercise equipment, so that additional device or apparatus is not required to detect the user's movement. In addition, the motion detection device (100), according to an embodiment of the present invention, may detect a movement even when it is not possible to detect the movement using an accelerometer and an gyrometer, because the motion detection device (100) is able to identify the type of exercise using the geomagnetic field data, even when the user and the motion detection device (100) are disposed apart from one another and the device is fixed (at a certain location or position) without moving.

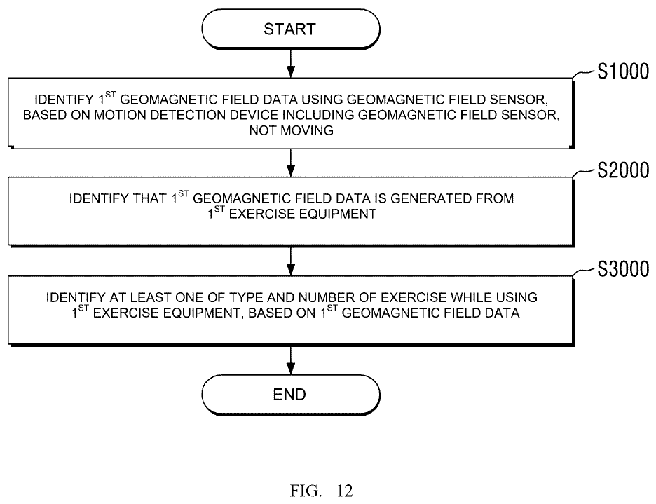

Hereinafter, a motion detection method using Earth's magnetic field, according to an embodiment of the present invention, are described with reference to FIG. 12. The steps included in the motion detection method using Earth's magnetic field described below may be implemented as instructions (commands) that may be performed (or executed) by a/the processor (120 of FIG. 1) of the motion detection device using Earth' magnetic field (100 of FIG. 1).

FIG. 12 shows a flowchart for describing the motion detection method using Earth's magnetic field, according to an embodiment of the present invention. For clarity of explanation, any details that overlap with those explained previously are simplified or omitted.

Referencing FIG. 12, the motion detection method using Earth's magnetic field, according to an embodiment of the present invention, may comprise a step (S1000) of identifying a 1st geomagnetic field data using a geomagnetic field sensor, based on the motion detection device, which includes a geomagnetic field sensor, not moving.

In certain embodiments, the motion detection method using Earth's magnetic field, according to an embodiment of the present invention, may comprise a step of identifying whether the motion detection device is moving. Whether the motion detection device is moving may be identified using at least one of an accelerometer and a gyrometer included in the motion detection device. Based on the motion detection device moving, a type of and a number of exercise may be identified using at least one of the accelerometer and the gyrometer. Based on the motion detection device not moving, the 1st geomagnetic field data may be identified using the geomagnetic field sensor.

In certain embodiments, the motion detection method using Earth's magnetic field, according to an embodiment of the present invention, may comprise a step of identifying a plurality of geomagnetic field data using the geomagnetic field sensor. The step of identifying the 1st geomagnetic field data (S1000) may include a step of identifying the 1st geomagnetic field data having the strongest intensity among the plurality of geomagnetic field data. For example, the motion detection method using Earth's magnetic field, according to an embodiment of the present invention, may comprise a step of identifying the intensity of each of the 1st geomagnetic field data and a 2nd geomagnetic field data when the 1st geomagnetic field data and the 2nd geomagnetic field data are identified. The motion detection method using Earth's magnetic field, according to an embodiment of the present invention, may comprise method for detecting motion using a geomagnetic field, according to an embodiment of the present invention, may identify the 1st geomagnetic field data having a stronger intensity among the 1st geomagnetic field data and the 2nd geomagnetic field data.

In certain embodiments, the motion detection method using Earth's magnetic field, according to an embodiment of the present invention, may comprise a step of performing pre-processing on the 1^{st} geomagnetic field data to identify the pre-processed 1st geomagnetic field data. The step of performing pre-processing may comprise a step of identifying a position of a motion detection device that is not moving, a step of identifying a direction of gravity, and a step of identifying the pre-processed 1st geomagnetic field data. The step of identifying the pre-processed 1st geomagnetic field data may comprise pre-processing the 1st geomagnetic field data based on a difference between the direction of gravity and the position of the motion detection device.

A motion detection method using a geomagnetic field, according to an embodiment of the present invention, may comprise a step (S2000) of identifying that the 1st geomagnetic field data is generated from a 1st moving motion device. Based on the periodicity of the 1st geomagnetic field data, the type of movement may be determined and the 1st exercise equipment may be identified.

In certain embodiments, the motion detection method using Earth's magnetic field, according to an embodiment of the present invention, may comprise a step of identifying the 1st geomagnetic field data and 2nd geomagnetic field data using the geomagnetic field sensor. the motion detection method using Earth's magnetic field, according to an embodiment of the present invention, may comprise a step of identifying that the 2nd geomagnetic field data is generated from a 2nd exercise equipment. The motion detection method using Earth's magnetic field, according to an embodiment of the present invention, may comprise a step of providing information for each of the 1st exercise equipment and the 2nd exercise equipment to the user, and identifying an input for selecting a/the exercise equipment. For example, an input for selecting the 1st exercise equipment among the 1st and the 2nd exercise equipment may be identified. The 1st geomagnetic field data may be selected based on the input, and at least one of the type and the number of exercise using the 1st exercise device may be identified based on the selected 1st geomagnetic field data. In certain embodiments, the 1st geomagnetic field data may be pre-processed.

According to an embodiment of the present invention, the motion detection method using Earth's magnetic field may include a step (S3000) of identifying at least one of the type of exercise and the number of the exercise, using the 1st exercise equipment based on the 1st geomagnetic field data.

In one or more of the embodiments, the 1st geomagnetic field data may be pre-processed 1st geomagnetic field data.

Various embodiments of the present disclosure may be implemented as software (e.g., a program), which includes one or more instructions stored in a storage medium (e.g., internal memory or external memory) that may be read by a machine (e.g., a motion detection device using Earth's magnetic field (100)). For example, the processor (110) of the machine (e.g., the motion detection device using Earth's magnetic field (100)) may call at least one instruction among the one or more instructions stored from the storage medium and execute it. This enables the machine to be operated to perform at least one function according to the at least one instruction called. The one or more instructions may include code generated by a compiler or code executable by an interpreter. A storage medium that may be read by the machine may be provided in a form of a non-transitory storage medium. Here, “non-transitory” means only that the storage medium is a tangible device and does not contain signals (e.g., electromagnetic waves), and the term does not distinguish between cases where data is stored semi-permanently or temporarily in the storage medium.

According to an embodiment, the methods according to the various embodiments disclosed in the present disclosure may be included in and provided as a computer program product. The computer program product may be traded between sellers and buyers as a commodity. The computer program product may be distributed in the form of a machine-readable storage medium (e.g., a compact disc read only memory (CD-ROM)), or may be distributed online (e.g., downloaded or uploaded) via an application store (e.g., Play Store™) or directly between two user devices (e.g., smartphones). In the case of online distribution, at least a part of the computer program product may be at least temporarily stored or temporarily generated in a machine-readable storage medium, such as a memory of a manufacturer's server, a server of an application store, or an intermediary server.

According to various embodiments, each of the components or elements (e.g., modules or programs) described above may include a single entity or multiple entities. According to various embodiments, one or more of the components or operations of the aforementioned components may be omitted, or one or more other components or operations may be added. Alternatively, or additionally, a plurality of the components (e.g., modules or programs) may be integrated into a single component. In such a case, the integrated component may perform one or more functions of each of the components of the plurality of components identically or similarly to those performed by the applicable or corresponding component of the plurality of components prior to the integration. According to various embodiments, the operations performed by the modules, programs or other components may be executed sequentially, in parallel, repeatedly, or heuristically, or one or more of the operations may be executed in a different order, omitted, or one or more other operations may be added.

The above description is merely an illustrative description of the technical spirit of the present embodiments, and those with ordinary skill in the art to which the present embodiments belongs may make various modifications and variations without departing from the essential characteristics and features of the present embodiments. Therefore, the present embodiments are not intended to limit the technical spirit of the present embodiments, but to explain them, and the scope of the technical spirit of the present embodiments is not limited by these embodiments. The technical scope of the present embodiments should be interpreted by the following claims, and all technical spirits, concept and ideas within a scope equivalent thereto should be interpreted as being included in the technical scope of and the scope of rights in the present embodiments of the present invention.

1. A motion detection device using Earth's magnetic field comprising
a geomagnetic field sensor,
a processor, and
a memory operatively connected to the processor,
wherein the memory enables the processor when executed to:
identify a 1st geomagnetic field data using the geomagnetic field sensor, based on that the motion detection device is not moving;
identify that the 1st geomagnetic field data is generated from a 1st exercise equipment that is moving; and
store instructions to identify at least one of a type of exercise and a number of the exercise using the 1st exercise equipment, based on the 1st geomagnetic field data.

2. The motion detection device using Earth's magnetic field of claim 1, wherein
the instructions enables the processor to:
identify a plurality of geomagnetic field data using the geomagnetic field sensor; and
identify the 1st exercise equipment from which the 1st geomagnetic field data is generated, based on the 1st geomagnetic field data having a strongest intensity among the plurality of the geomagnetic field data.

3. The motion detection device using Earth's magnetic field of claim 2, wherein
a plurality of exercise equipment comprises a 1st exercise equipment and a 2nd exercise equipment, and
the instructions enables the processor to:
identify the 1st geomagnetic field data and the 2nd geomagnetic field data, using the geomagnetic field sensor; and
identify the 1st exercise equipment from which the 1st geomagnetic field data is generated, based on the 1st geomagnetic field data having a stronger intensity among the 1st geomagnetic field data and the 2nd geomagnetic field data.

4. The motion detection device using Earth's magnetic field of claim 1, wherein
the instructions enables the processor to:
identify the 1st geomagnetic field data and a 2nd geomagnetic field data, using the geomagnetic field sensor;
identify that the 2nd geomagnetic field data is generated from a 2nd exercise equipment that is moving;
identify an input for selecting the 1st exercise equipment among the 1st exercise equipment and the 2nd exercise equipment; and
based on the input, identify at least one of the type and the number of the exercise using the 1st exercise equipment, based on the 1st geomagnetic field data.

5. The motion detection device using Earth's magnetic field of claim 4, wherein
the instructions enables the processor to:
based on the input, perform pre-processing on the 1st geomagnetic field data and identify the 1st geomagnetic field data that is pre-processed; and
identify at least one of the type and number of the exercise using the 1st exercise equipment, based on the pre-processed 1st geomagnetic field data.

6. The motion detection device using Earth's magnetic field of claim 5, wherein
the instructions enables the processor to:
identify a position of the motion detection device that is not moving;
identify a direction of gravity; and
pre-process the 1st geomagnetic field data based on a difference of the position of the motion detection device and the direction of gravity, and identify the pre-processed 1st geomagnetic field data.

7. The motion detection device using Earth's magnetic field of claim 1, wherein
the instructions enables the processor to:
pre-process the 1st geomagnetic field data, and identify the pre-processed 1st geomagnetic field data; and
identify at least one of the type and the number of the exercise using the 1st exercise equipment, based on the pre-processed 1st geomagnetic field data.

8. The motion detection device using Earth's magnetic field of claim 7, wherein
the instructions enables the processor to:
identify a position of the motion detection device that is not moving;
identify a direction of gravity; and
pre-process the 1st geomagnetic field data based on a difference of the position of the motion detection device and the direction of gravity, and identify the pre-processed 1st geomagnetic field data.

9. The motion detection device using Earth's magnetic field of claim 1, wherein
the instructions enables the processor to:
identify whether the motion detection device is moving by using at least one of an accelerometer and a gyrometer, which are included in the motion detection device; and
identify the 1st geomagnetic field data using the geomagnetic field sensor, based on that the motion detection device is not moving.

10. The motion detection device using Earth's magnetic field of claim 1, wherein
the motion detection device comprising the geomagnetic field sensor is a mobile device.

11. A motion detection method using Earth's magnetic field, comprising:
a step of identifying a 1st geomagnetic field data using a geomagnetic field sensor, based on that the motion detection device comprising the geomagnetic field sensor is not moving;
a step of identifying that the 1st geomagnetic field data is generated from a 1st exercise equipment that is moving; and
a step of identifying at least one of a type of exercise and a number of the exercise using the 1st exercise equipment, based on the 1st geomagnetic field data.

12. The motion detection method using Earth's magnetic field of claim 11, further comprising
a step of identifying a plurality of geomagnetic field data using the geomagnetic field sensor; and
wherein
the step of identifying the 1st geomagnetic field data using the geomagnetic field sensor comprises
a step of identifying the 1st geomagnetic field data having a strongest intensity among the plurality of the geomagnetic field data.

13. The motion detection method using Earth's magnetic field of claim 12, wherein
a plurality of exercise equipment comprises a 1st exercise equipment and a 2nd exercise equipment; and
wherein
the step of identifying the 1st geomagnetic field data having the strongest intensity among the plurality of the geomagnetic field data, comprises:
a step of identify the 1st geomagnetic field data and the 2nd geomagnetic field data, using the geomagnetic field sensor; and
a step of identifying an intensity of the 1st geomagnetic field data and an intensity of the 2nd geomagnetic field data.

14. The motion detection method using Earth's magnetic field of claim 11, further comprising:
a step of identifying the 1st geomagnetic field data and a 2nd geomagnetic field data, using the geomagnetic field sensor;
a step of identifying that the 2nd geomagnetic field data is generated from a 2nd exercise equipment that is moving; and
a step of identify an input for selecting the 1st exercise equipment among the 1st exercise equipment and the 2nd exercise equipment; and
wherein based on the input,
the step of identifying at least one of the type and the number of the exercise using the 1st exercise equipment, based on the 1st geomagnetic field data, comprises
a step of selecting the 1st geomagnetic field data, based on the input.

15. The motion detection method using Earth's magnetic field of claim 14, further comprising
a step of pre-processing the 1st geomagnetic field data and identifying the pre-processed 1st geomagnetic field data, and
wherein
the step of identifying at least one of the type and the number of the exercise using the 1st exercise equipment is performed based on the pre-processed 1st geomagnetic field data.

16. The motion detection method using Earth's magnetic field of claim 15, wherein
the step of pre-processing the 1st geomagnetic field data and identifying the pre-processed 1st geomagnetic field data, comprises:
a step of identifying a position of the motion detection device that is not moving;
a step of identifying a direction of gravity; and
a step of pre-processing the 1st geomagnetic field data based on a difference of the position of the motion detection device and the direction of gravity, and identifying the pre-processed 1st geomagnetic field data.

17. The motion detection method using Earth's magnetic field of claim 11, further comprising
a step of pre-processing the 1st geomagnetic field data, and identifying the pre-processed 1st geomagnetic field data, and
wherein
the step of identifying at least one of the type and the number of the exercise using the 1st exercise equipment is performed based on the pre-processed 1st geomagnetic field data.

18. The motion detection method using Earth's magnetic field of claim 17, wherein
the step of pre-processing the 1st geomagnetic field data, and identifying the pre-processed 1st geomagnetic field data, comprises:
a step of identifying a position of the motion detection device that is not moving;
a step of identifying a direction of gravity; and
a step of pre-processing the 1st geomagnetic field data based on a difference of the position of the motion detection device and the direction of gravity, and identifying the pre-processed 1st geomagnetic field data.

19. The motion detection method using Earth's magnetic field of claim 11, further comprising:
a step of identifying whether the motion detection device is moving by using at least one of an accelerometer and a gyrometer, which are included in the motion detection device; and
a step of identifying the 1st geomagnetic field data using the geomagnetic field sensor, based on that the motion detection device is not moving.

20. The motion detection method using Earth's magnetic field of claim 11, wherein
the motion detection device comprising the geomagnetic field sensor is a mobile device.
